(19) United States
(12) Patent Application Publication
(10) Pub. No.: US 2015/0060114 A1
(43) Pub. Date: Mar. 5, 2015

(54) RIGID FLEXIBLE PCB AND METHOD FOR MANUFACTURING THE SAME

(71) Applicant: SAMSUNG ELECTRO-MECHANICS CO., LTD., Suwon (KR)

(72) Inventors: Jung Yong PARK, Busan (KR); Tae Ho Ko, Busan (KR); Seok Cheol Song, Busan (KR)

(73) Assignee: SAMSUNG ELECTRO-MECHANICS CO., LTD., Suwon (KR)

(21) Appl. No.: 14/087,533

(22) Filed: Nov. 22, 2013

(30) Foreign Application Priority Data
Sep. 2, 2013 (KR) 10-2013-0104834

(51) Int. Cl. H05K 3/46; H05K 1/09; H05K 1/11; H05K 1/02

(52) U.S. Cl. CPC H05K 3/4691; H05K 3/4673; H05K 1/028; H05K 1/09; H05K 1/115; H05K 1/0298; H05K 2203/14
USPC 174/254; 29/17.3

(57) ABSTRACT

Disclosed herein is a rigid flexible printed circuit board (PCB) including: a flexible area having a flexible copper foil laminate in which circuit layers are formed on an insulating material, and cover lays formed on the laminate; and rigid areas having insulating layers and copper layers built-up on both sides of the flexible area, and flattening materials to flatten outer surfaces of the insulating layers.

### CROSS REFERENCE(S) TO RELATED APPLICATIONS

This application claims the benefit under 35 U.S.C. Section 119 of Korean Patent Application Serial No. 10-2013-0104834, entitled “Rigid Flexible PCB and Method for Manufacturing the Same” filed on Sep. 2, 2013, which is hereby incorporated by reference in its entirety into this application.

### BACKGROUND OF THE INVENTION

1. Technical Field

The present invention relates to a rigid flexible PCB and a method for manufacturing the same, and more particularly, to a rigid flexible PCB with improved flatness and a method for manufacturing the same.

2. Description of the Related Art

Recently, mobile electronic devices have evolved to have high performance and to support the Internet, video and massive data transmission. Accordingly, the design of the printed circuit board becomes more complicated, and highly densed and smaller circuits are increasingly required.

Therefore, printed circuit boards incorporated in electronic devices become thinner and smaller, and thus the width of wiring on the printed circuit boards also becomes smaller in order to implement the functions of the printed circuit boards. The structure of the printed circuit boards is changing from a single layer to multiple layers.

Currently, in the process of manufacturing a rigid flexible printed circuit board, a cover lay, an electromagnetic interference (EMI) filter and the like are manufactured on the flexible board in separate processes, and stacked on the insulating material to be cured.

Further, in the process of manufacturing a rigid flexible printed circuit board, cover lays are applied on the surface of a flexible copper clad laminate (FCCL), then they are compressed at a high temperature of approximately 170° C. by the substrate molding members, and the cover lays and the FCCL are integrally molded.

When the cover lays and the FCCL are integrally molded by the substrate molding members, however, smooth waves are formed on the surfaces of the cover lays conforming to the shape of the circuit layers. Thus, Layers such as prepreg and copper layers are formed on the wave surfaces, the surface of the rigid board becomes uneven, thereby decreasing product value.

### RELATED ART DOCUMENT

### Patent Document

(Patent Document 1) Cited Reference: Korean Patent Laid-Open Publication No. 2012-0007444

### SUMMARY OF THE INVENTION

An object of the present invention is to provide a rigid flexible PCB capable of improving deviations in the overall thickness of the board by way of adding a rigid flattening material in the board when the rigid board is manufactured, and a method for manufacturing the same.

Another object of the present invention is to provide a rigid flexible PCB capable of suppressing warpage by virtue of a rigid flattening material stacked in the rigid board.

According to an exemplary embodiment of the present invention, there is provided a rigid flexible printed circuit board (PCB) including: a flexible area having a flexible copper foil laminate in which circuit layers are formed on an insulating material, and cover lays formed on the laminate; and rigid areas having insulating layers and copper layers built-up on both sides of the flexible area, and flattening materials to flatten outer surfaces of the insulating layers.

The flattening material may be stacked between the insulating layers and the copper layers and may be formed of a copper foil laminate.

The circuit layers and the copper layers may be electrically connected via a through via penetrating through the flattening materials and the insulating layers, and the flattening material may be formed of a rigid insulating material.

### BRIEF DESCRIPTION OF THE DRAWINGS

FIG. 1 is a cross-sectional view of a manufactured rigid flexible PCB according to an exemplary embodiment of the present invention; and

FIGS. 2A to 2F are views showing a manufacturing process of the rigid flexible PCB according to an exemplary embodiment of the present invention.

### DESCRIPTION OF THE PREFERRED EMBODIMENTS

Hereinafter, exemplary embodiments of the present invention will be described in detail with reference to the accompanying drawings.

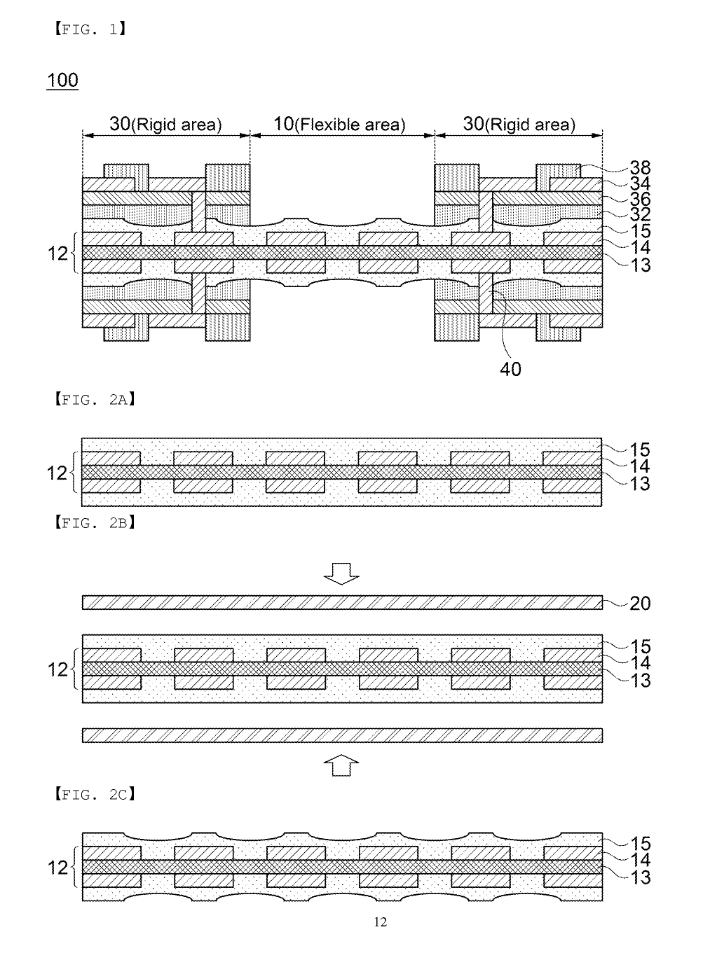

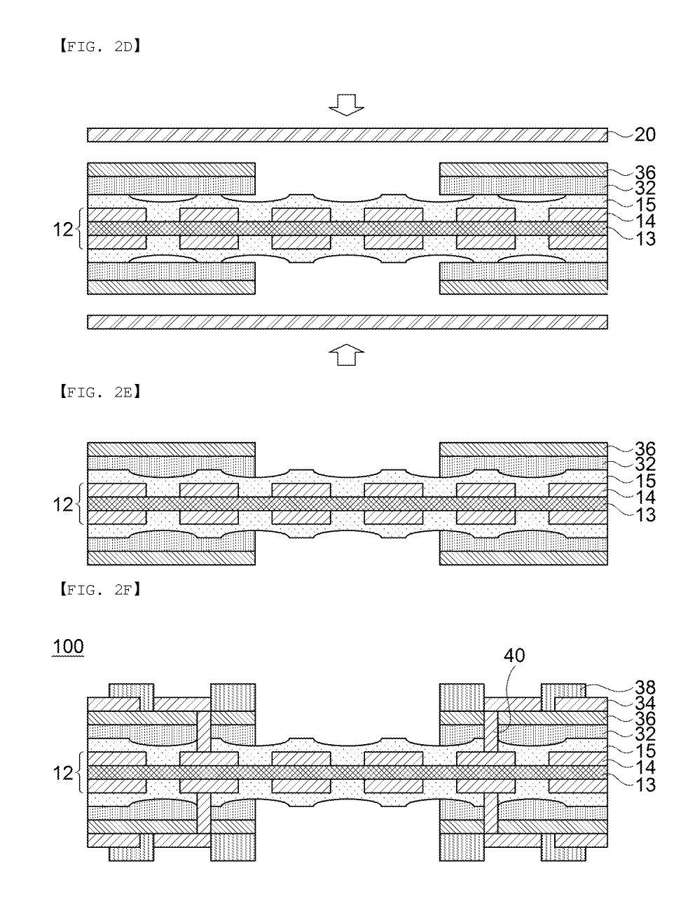

FIG. 1 is a cross-sectional view of a manufactured rigid flexible PCB according to an exemplary embodiment of the present invention; and FIGS. 2A to 2F are views showing a manufacturing process of the rigid flexible PCB according to an exemplary embodiment of the present invention.

As shown in FIG. 1, the rigid flexible PCB 100 according to the exemplary embodiment of the present invention includes a flexible area 10 and rigid areas 30 on both sides of the flexible area 10.

The flexible area 10 includes an insulating material 13 formed of polyimide or prepreg, a flexible copper foil laminate 12 having circuit layers 14 formed on both surfaces of the insulating material 13, and cover lays stacked on the flexible copper foil laminate 12.

Preferably, the insulating material 13 is thinner than or equal to the circuit layers 14. This is to prevent the circuit layers 14 from being readily delaminated from the insulating material 13 by ensuring sufficient tension against impact from the outside.

The circuit layers 14 are formed by performing etching on copper foils formed the both surfaces of the insulating material 13 and may be formed of a material having good conductivity such as copper.

Further, over the circuit layers 14, the cover lays 15 are thermo-compression molded at high temperature by substrate molding members 20.

The cover lays 15 are thermo-compression molded by the substrate molding members 20 under a pressure of approximately 25 kg/cm² or greater at a temperature of approximately 170° C. or higher and then the substrate molding members 20 are separated from the cover lays 15 and the cover lays 15 are cured.

Here, when the substrate molding members 20 are separated from the cover lays 15, waves are made on the outer surfaces of the cover lays 15. This is because the portions on the upper surfaces of the cover lays 15 where the circuit layers 14 are formed protrude than the portions where the circuit layers 14 are not formed depending on the shapes and locations of the circuit layers 14 when the cover lays 15 are pressed by the substrate molding members 20.

After the cover lays 15 are thermo-compression molded as described above, the rigid areas 30 are formed on both sides of the flexible area 10.

The rigid areas 30 include insulating layers 32, copper layers 34, and flattening material 36 interposed between the copper layers 34 and the insulating layers 32.

Further, the rigid areas 30 may further include photo solder resist (PSR) layers 38 applied on the copper layers 34.

The insulating layers 32 may be applied on both surfaces of the cover lays 15 and may be formed of prepreg. The insulating layers 32 are designed to have such a thickness as to maintain rigidity sufficient to suppress warpage.

After the insulating layers 32 are stacked on the cover lays 15 as described above, the flattening materials 36 are stacked on the insulating layers 32.

The flattening materials 36 may be a copper foil laminate formed by laminating copper foils on insulating materials and, if necessary, may be a rigid insulating material having a melting point higher than that of the insulating layers 32.

That is, after the insulating layers 32 and the flattening materials 36 are stacked on the cover lays 15 in this order, by performing thermo-compression molding at a high temperature while bringing the substrate molding members 20 into close contact with the flattening material 36, part of the insulating layers 32 is melted so as to fill the space on the recessed portions on the cover lays 15.

Here, although the upper surfaces of the insulating layer 32 may have a smooth wave as the circuit layers 14 during the compression molding process, since the upper surfaces of the insulating layers 32 are in close contact with the flattening material 36 while they are compression molded, the smooth wave on the upper surfaces of the insulating layers 32 do not affect the copper layers 34 stacked on the flattening materials 36.

The copper layers 34 are formed on the flattening materials 36 and formed by performing etching process or the like after copper foils are formed. After the copper layers 34 are formed, photo solder resist layers 38 are formed.

Here, electrical connections between the layers are made by through vias 40. That is, the circuit layers 14 and the copper layers 34 are electrically connected through the through vias 40 penetrating through the flattening materials 36 and the insulating layers 32. The through vias 40 may be formed by being penetrated by laser to form a hole and then being plated.

The rigid flexible PCB thus configured may be manufactured according to the following process.

As shown in FIGS. 2A and 2B, copper foils are formed on both surfaces of the insulating layer 13, and then an etching process is performed on the copper foils to form circuit layers 14.

After flexible copper foil laminate 12 is manufactured by forming the circuit layers 14, cover lays 15 are applied on both surfaces of the circuit layers 14. The cover lays 15 are thermo-compression molded by the substrate molding members 20 under a pressure of approximately 25 kg/cm² or greater at a temperature of approximately 170° C. or higher.

After the cover lays 15 are thermo-compression molded for a certain period of time by the substrate molding members 20, the substrate molding members 20 are separated from the cover lays 15, and the cover lays 15 are air-cooled and cured, to manufacture a flexible area 10.

Once the flexible area 10 is manufactured as described above, the insulating layers 32 and the flattening materials 36 are stacked on both surfaces of the flexible area 10 in this order. Here, the insulating layers 32 may be formed of an insulating material such as prepreg, and the flattening materials 36 may be formed of a rigid material such as a copper foil laminate.

After the insulating layers 32 and the flattening materials 36 are stacked, they are thermo-compression molded by the substrate molding members 20 at a high temperature. After a certain period of time for the compression, the substrate molding members 20 are separated from the flattening materials 36 and air-cooling is performed.

After air-cooling is completed, copper layers 34 are formed on the flattening materials 36, and photo solder resist layers 38 are formed on the copper layers 34. Here, electrical connections between the layers are made by through vias 40. The through vias 40 may be formed according to a method well known in the art for providing electrical connections between layers, and thus detail description thereon will not be given.

Accordingly, in the rigid flexible PCB 100 according to the exemplary embodiment of the present invention, waves formed between the cover lays 15 and the insulating layers 32 conforming to the shape of the circuit layers 14 can be flattened by the rigid flattening materials 36. As a result, overall warpage of the board can be suppressed and thus product value can be improved.

According to the exemplary embodiments of the present invention, a rigid flattening material is added in the board when the rigid board is manufactured, so that deviations in the overall thickness of the board is improved, as well as warpage is suppressed by virtue of a rigid flattening material. Therefore, product value can be improved.

Thus far, although the rigid flexible PCB and the method for manufacturing the same have been described according to the exemplary embodiment of the present invention, the present invention is not limited thereto, but may be variously modified and altered by those skilled in the art.

What is claimed is:

1. A rigid flexible printed circuit board (PCB) comprising:
a flexible area having a flexible copper foil laminate in which circuit layers are formed on an insulating material, and cover lays formed on the laminate; and
rigid areas having insulating layers and copper layers built-up on both sides of the flexible area, and flattening materials to flatten outer surfaces of the insulating layers.

2. The rigid flexible printed circuit board according to claim 1, wherein the flattening materials are stacked on the insulating layers.

3. The rigid flexible printed circuit board according to claim 1, wherein the flattening materials are formed of copper foil laminates.

4. The rigid flexible printed circuit board according to claim 1, wherein the circuit layers and the copper layers are electrically connected via a through via penetrating through the flattening materials and the insulating layers.

5. The rigid flexible printed circuit board according to claim 1, wherein the flattening materials are formed of rigid insulating material.

6. A method of manufacturing a rigid flexible printed circuit board, the method comprising:
applying cover lays on flexible copper foil laminates;
thermo-compression molding the cover lays at a high temperature using substrate molding members;
stacking insulating layers and flattening materials in this order on both surfaces of the thermo-compression molded cover lays;
thermo-compression molding the flattening materials at a high temperature using the substrate molding members; and
forming copper layers on the flattening materials to form photo solder resist layers on the copper layers.

7. The method according to claim 6, wherein the cover lays are thermo-compression molded by the substrate molding members under a pressure of approximately 25 kg/cm² or greater at a temperature of approximately 170° C. or higher.
